(19) United States
(12) Patent Application Publication
(10) Pub. No.: US 2025/0200877 A1
(43) Pub. Date: Jun. 19, 2025

(54) CONTROL APPARATUS

(71) Applicant: TOYOTA JIDOSHA KABUSHIKI KAISHA, Toyota-shi (JP)

(72) Inventors: Yuki TATSUMOTO, Seto-shi (JP); Takuya MAEKAWA, Kashiba-shi (JP); Hiroyasu SHIOKAWA, Nagoya-shi (JP); Shunsuke SAGARA, Nisshin-shi (JP); Makoto TAMURA, Miyoshi-shi (JP)

(73) Assignee: TOYOTA JIDOSHA KABUSHIKI KAISHA, Toyota-shi (JP)

(21) Appl. No.: 18/970,898

(22) Filed: Dec. 6, 2024

(30) Foreign Application Priority Data
Dec. 15, 2023 (JP) 2023-212428

(51) Int. Cl. G06T 17/00; G06F 30/15

(52) U.S. Cl. CPC G06T 17/00; G06F 30/15

(57) ABSTRACT

A control apparatus includes a communication interface configured to communicate with a terminal apparatus of a user, and a controller configured to acquire first vehicle type data indicating a type of a vehicle ordered by the user as a first vehicle type and second vehicle type data indicating a type of a vehicle used by the user as a second vehicle type, generate a first image representing at least a part of a first field of view range visible in a vehicle of the first vehicle type indicated by the acquired first vehicle type data and a second image representing at least a part of a second field of view range visible in a vehicle of the second vehicle type indicated by the acquired second vehicle type data, and transmit both of the generated first image and second image to the terminal apparatus of the user via the communication interface.

### CROSS-REFERENCE TO RELATED APPLICATION

This application claims priority to Japanese Patent Application No. 2023-212428, filed on Dec. 15, 2023, the entire contents of which are incorporated herein by reference.

### TECHNICAL FIELD

The present disclosure relates to a control apparatus.

### BACKGROUND

Patent Literature (PTL) 1 discloses an information provision apparatus that provides a user with information on the progress of a particular vehicle until delivery. This apparatus provides a user terminal with, for example, captured images during assembly or positional information during transport.

### CITATION LIST

### Patent Literature

PTL 1: JP 2002-297954 A

### SUMMARY

The conventional apparatus does not allow a customer to know the change in the sense of operation or visibility when using a vehicle as a result of changing vehicles, and convenience is insufficient.

It would be helpful to enable a user to know the change in the sense of operation or visibility when using a vehicle as a result of changing vehicles.

A control apparatus according to the present disclosure includes:
a communication interface configured to communicate with a terminal apparatus of a user; and
a controller configured to:
   acquire first vehicle type data indicating a type of a vehicle ordered by the user as a first vehicle type and second vehicle type data indicating a type of a vehicle used by the user as a second vehicle type;
   generate a first image representing at least a part of a first field of view range visible in a vehicle of the first vehicle type indicated by the acquired first vehicle type data and a second image representing at least a part of a second field of view range visible in a vehicle of the second vehicle type indicated by the acquired second vehicle type data; and
   transmit both of the generated first image and second image to the terminal apparatus of the user via the communication interface.

According to the present disclosure, a user can know the change in the sense of operation or visibility when using a vehicle as a result of changing vehicles, which increases convenience.

### BRIEF DESCRIPTION OF THE DRAWINGS

In the accompanying drawings:

FIG. 1 is a diagram illustrating a configuration of a system according to an embodiment of the present disclosure;

FIG. 2 is a block diagram illustrating a configuration of a control apparatus according to the embodiment of the present disclosure; and

FIG. 3 is a flowchart illustrating operations of the control apparatus according to the embodiment of the present disclosure.

### DETAILED DESCRIPTION

An embodiment of the present disclosure will be described below, with reference to the drawings.

In the drawings, the same or corresponding portions are denoted by the same reference numerals. In the descriptions of the present embodiment, detailed descriptions of the same or corresponding portions are omitted or simplified, as appropriate.

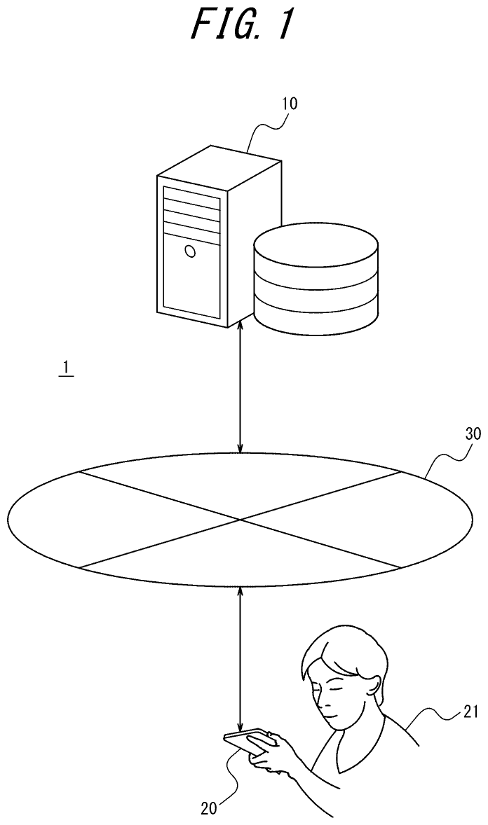

A configuration of a system 1 according to the present embodiment will be described with reference to FIG. 1.

The system 1 according to the present embodiment includes a control apparatus 10 and a terminal apparatus 20. The control apparatus 10 can communicate with the terminal apparatus 20 via a network 30.

The control apparatus 10 is a server computer such as a cloud server in the present embodiment, but it may be a general purpose computer such as a PC, a microcomputer mounted in a mobile device such as a smartphone or tablet, or a dedicated computer. The term “PC” is an abbreviation of personal computer. In the present embodiment, the control apparatus 10 is operated by the vehicle production operator. The control apparatus 10 may be integrated with the terminal apparatus 20, for example, it may be a microcomputer mounted on the terminal apparatus 20.

The terminal apparatus 20 is a computer capable of installing and executing application programs, such as a PC mobile phone, smartphone, or tablet. The terminal apparatus 20 is used by a user 21.

The network 30 includes the Internet, at least one WAN, at least one MAN, or any combination thereof. The term “WAN” is an abbreviation of wide area network. The term “MAN” is an abbreviation of metropolitan area network. The network 30 may include at least one wireless network, at least one optical network, or any combination thereof. The wireless network is, for example, an ad hoc network, a cellular network, a wireless LAN, a satellite communication network, or a terrestrial microwave network. The term “LAN” is an abbreviation of local area network.

An outline of the present embodiment will be described with reference to FIG. 1.

In the present embodiment, the control apparatus 10 communicates with the terminal apparatus 20 of the user 21. The control apparatus 10 acquires the first vehicle type data indicating the type of a vehicle N ordered by the user 21 as the first vehicle type and the second vehicle type data indicating the type of a vehicle C used by the user 21 as the second vehicle type. The “vehicle type” refers in the present embodiment to the unique name given by the vehicle producer as the type of vehicle, i.e., the model of the vehicle, but it may also refer to a broader classification, such as a legal classification, or a more detailed classification, such as the year or grade of the vehicle. The control apparatus 10 generates a first image representing at least a part of the first field of view range visible in a vehicle of the first vehicle type indicated by the acquired first vehicle type data and a second image representing at least a part of the second field of view range visible in a vehicle of the second vehicle type indicated by the acquired second vehicle type data. The control apparatus 10 transmits both of the generated first image and second image to the terminal apparatus 20 of the user 21.

According to the present embodiment, the user 21 can know the change in the sense of operation or visibility as a result of changing vehicles, which increases convenience.

In the present embodiment, the user 21 is a purchaser who has ordered the vehicle N and is waiting for delivery. The user 21 is currently using the vehicle C of the second vehicle type, which is different from the first vehicle type.

The data indicating the first vehicle type is entered into the dedicated server by the vehicle producer, for example, at the time of ordering by the user 21 as the first vehicle type data. Dedicated servers can be cloud servers or on-premise servers installed at the vehicle manufacturer's offices or other locations. Alternatively, the first vehicle type data may be entered into the terminal apparatus 20 by the user 21. In other words, the first vehicle type data is stored on a dedicated server or the terminal apparatus 20.

The data indicating the second vehicle type is entered into the terminal apparatus 20 by the user 21 as the second vehicle type data. Alternatively, the second vehicle type data may be entered into the dedicated server by the vehicle producer, for example, at the time of ordering by the user 21. In other words, the second vehicle type data is stored on a dedicated server or the terminal apparatus 20.

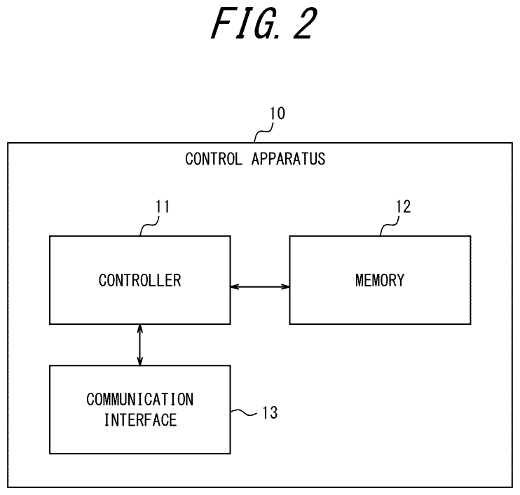

A configuration of the control apparatus 10 according to the present embodiment will be described with reference to FIG. 2.

The control apparatus 10 includes a controller 11, a memory 12, and a communication interface 13.

The controller 11 includes at least one processor, at least one programmable circuit, at least one dedicated circuit, or any combination thereof. The processor is a general purpose processor such as a CPU or a GPU, or a dedicated processor that is dedicated to specific processing. The term “CPU” is an abbreviation of central processing unit. The term “GPU” is an abbreviation of graphics processing unit. The programmable circuit is, for example, an FPGA. The term “FPGA” is an abbreviation of field-programmable gate array. The dedicated circuit is, for example, an ASIC. The term “ASIC” is an abbreviation of application specific integrated circuit. The controller 11 executes processes related to operations of the control apparatus 10 while controlling components of the control apparatus 10.

The memory 12 includes at least one semiconductor memory, at least one magnetic memory, at least one optical memory, or any combination thereof. The semiconductor memory is, for example, RAM, ROM, or flash memory. The term “RAM” is an abbreviation of random access memory. The term “ROM” is an abbreviation of read only memory. The RAM is, for example, SRAM or DRAM. The term “SRAM” is an abbreviation of static random access memory. The term “DRAM” is an abbreviation of dynamic random access memory. The ROM is, for example, EEPROM. The term “EEPROM” is an abbreviation of electrically erasable programmable read only memory. The flash memory is, for example, SSD. The term “SSD” is an abbreviation of solid-state drive. The magnetic memory is, for example, HDD. The term “HDD” is an abbreviation of hard disk drive. The memory 12 functions as, for example, a main memory, an auxiliary memory, or a cache memory. The memory 12 stores data to be used for the operations of the control apparatus 10 and data obtained by the operations of the control apparatus 10.

The communication interface 13 includes at least one communication module. The communication module is, for example, a module compatible with a wired LAN communication standard such as Ethernet® (Ethernet is a registered trademark in Japan, other countries, or both), a wireless LAN communication standard such as IEEE802.11, or a mobile communication standard such as LTE, the 4G standard, or the 5G standard. The name “IEEE” is an abbreviation of Institute of Electrical and Electronics Engineers. The term “LTE” is an abbreviation of Long Term Evolution. The term “4G” is an abbreviation of 4th generation. The term “5G” is an abbreviation of 5th generation. The communication interface 13 communicates with the terminal apparatus 20 via the network 30. The communication interface 13 receives data to be used for the operations of the control apparatus 10, and transmits data obtained by the operations of the control apparatus 10.

The functions of the control apparatus 10 are realized by execution of a program according to the present embodiment by a processor serving as the controller 11. That is, the functions of the control apparatus 10 are realized by software. The program causes a computer to execute the operations of the control apparatus 10, thereby causing the computer to function as the control apparatus 10. That is, the computer executes the operations of the control apparatus 10 in accordance with the program to thereby function as the control apparatus 10.

The program can be stored on a non-transitory computer readable medium. The non-transitory computer readable medium is, for example, flash memory, a magnetic recording device, an optical disc, a magneto-optical recording medium, or ROM. The program is distributed, for example, by selling, transferring, or lending a portable medium such as an SD card, a DVD, or a CD-ROM on which the program is stored. The term “SD” is an abbreviation of Secure Digital. The term “DVD” is an abbreviation of digital versatile disc. The term “CD-ROM” is an abbreviation of compact disc read only memory. The program may be distributed by storing the program in a storage of a server and transferring the program from the server to another computer. The program may be provided as a program product.

For example, the computer temporarily stores, in a main memory, a program stored in a portable medium or a program transferred from a server. Then, the computer reads the program stored in the main memory using a processor, and executes processes in accordance with the read program using the processor. The computer may read a program directly from the portable medium, and execute processes in accordance with the program. The computer may, each time a program is transferred from the server to the computer, sequentially execute processes in accordance with the received program. Instead of transferring a program from the server to the computer, processes may be executed by a so-called ASP type service that realizes functions only by execution instructions and result acquisitions. The term “ASP” is an abbreviation of application service provider. The program encompasses information that is to be used for processing by an electronic computer and is thus equivalent to a program. For example, data that is not a direct command to a computer but has a property that regulates processing of the computer is “equivalent to a program” in this context.

Some or all of the functions of the control apparatus 10 may be realized by a programmable circuit or a dedicated circuit serving as the controller 11. That is, some or all of the functions of the control apparatus 10 may be realized by hardware.

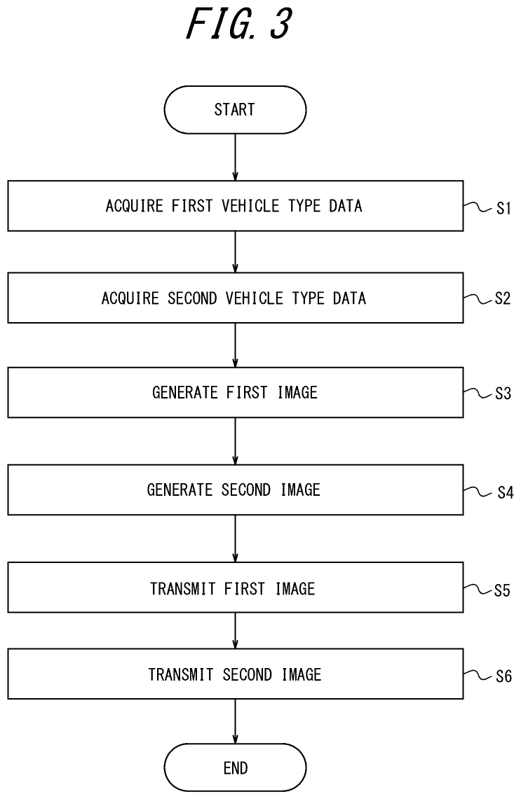

Operations of the control apparatus 10 according to the present embodiment will be described with reference to FIG. 3. The operations described below correspond to a control method according to the present embodiment. In other words, the control method according to the present embodiment includes steps SI to S6 illustrated in FIG. 3.

For example, when the user 21 presses the “Compare” button on the terminal apparatus 20, step S1 is initiated.

In S1, the controller 11 acquires the first vehicle type data. Specifically, the controller 11 acquires the first vehicle type data from the dedicated server or from the terminal apparatus 20 via the communication interface 13. The acquired first vehicle type data is stored in the memory 12.

In S2, the controller 11 acquires the second vehicle type data. Specifically, the controller 11 acquires the second vehicle type data from the terminal apparatus 20 via the communication interface 13. Alternatively, the controller 11 may acquire the second vehicle type data from a dedicated server via the communication interface 13. The acquired second vehicle type data is stored in the memory 12.

In S3, the controller 11 generates the first image. In the present embodiment, the first image is generated by the controller 11 selecting and, if necessary, editing a part of the first field of view data. The first field of view data is image data of multiple vehicle types, including the first vehicle type. For example, the first field of view data includes images of various vehicle exteriors, interiors, parts, or operation buttons. The first field of view data is stored in the memory 12 in advance. Alternatively, the first field of view data may be stored on a dedicated server. The controller 11 acquires one or more images of the first vehicle type included in the first field of view data from the memory 12 or from a dedicated server via the communication interface 13. The controller 11 edits the acquired image as necessary to generate the first image. Alternatively, if two or more images are acquired, the controller 11 combines those two or more images to generate the first image.

As a first example, the controller 11 may generate as the first image an image including, as at least a part of the first field of view range, a screen to be displayed on a display mounted in a vehicle of the first vehicle type. The screen of the display mounted in the vehicle of the first vehicle type is, for example, the screen of the operation buttons, electronic meters, navigation system, or rearview monitor on the in-vehicle display. The user 21 may be able to operate the screen displayed in the image to simulate functions such as connected services.

As a second example, the controller 11 may generate as the first image an image including, as at least a part of the first field of view range, a physical object to be used for an operation in the vehicle of the first vehicle type. Operations are, for example, operation and in-vehicle equipment operation. The physical objects used for operation are, for example, handles, pedals and handle brakes used for driving operations, switches used to operate the air conditioning units that are in-vehicle equipment, or buttons to open and close windows. The user 21 may be able to operate these physical objects displayed in the image to simulate functions such as how to start the engine.

As a third example, the controller 11 may generate as the first image an image including, as at least a part of the first field of view range, a view visible from the driver seat through a window of the vehicle of the first vehicle type. The view visible from the driver seat through the window is, for example, the view outside the vehicle of the first vehicle type visible through the window when driving or parking. For example, a user can check blind spots when driving by looking at the view visible from the driver seat.

As a fourth example, the controller 11 may generate an image included in a model of the vehicle of the first vehicle type reproduced in a virtual space as the first image. The virtual space is, for example, a metaverse. The metaverse is a three-dimensional virtual space constructed on the Internet. The user 21 may be able to simulate getting into a vehicle of the first vehicle type reproduced in the metaverse, or opening and closing doors, etc.

In S4, the controller 11 generates the second image. In the present embodiment, the second image is generated by the controller 11 selecting and, if necessary, editing a part of the second field of view data. The second field of view data is image data of multiple vehicle types, including the second vehicle type. For example, the second field of view data includes images of various vehicle exteriors, interiors, parts, or operation buttons. The second field of view data is stored in the memory 12 in advance. Alternatively, the second field of view data may be stored on a dedicated server. The controller 11 acquires one or more images of the vehicle of the second vehicle type included in the second field of view data from the memory 12 or from a dedicated server via the communication interface 13. The controller 11 edits the acquired image as necessary to generate the second image. Alternatively, if two or more images are acquired, the controller 11 combines those two or more images to generate a second image.

The second image generated by the controller 11 in S4 is an image of the field of view range corresponding to the first field of view range of the first image. In other words, the controller 11 generates a second image that represents the field of view range corresponding to the first field of view range of the first image generated in S3.

Corresponding to the first example of the first image, the controller 11 may generate as the second image an image including, as at least a part of the second field of view range, a screen to be displayed on a display mounted in a vehicle of the second vehicle type. The screen of the display mounted in the vehicle of the second vehicle type is, for example, the screen of the operation buttons, electronic meters, navigation system, or rearview monitor on the in-vehicle display. The user 21 may be able to operate these screens displayed on the image to reconfirm features such as connected services.

Corresponding to the second example of the first image, the controller 11 may generate as the second image an image including, as at least a part of the second field of view range, a physical object to be used for an operation in the vehicle of the second vehicle type. Operations are, for example, operation and in-vehicle equipment operation. The physical objects used for operation are, for example, handles, pedals and handle brakes used for driving operations, switches used to operate the air conditioning units that are in-vehicle equipment, or buttons to open and close windows. The user 21 may be able to operate these physical objects displayed in the image to reconfirm the functionality, such as how the engine is turned on.

Corresponding to the third example of the first image, the controller 11 may generate as the second image an image including, as at least a part of the second field of view range, a view visible from the driver seat through a window of the vehicle of the second vehicle type. The view visible from the driver seat through the window is, for example, the view outside the vehicle of the second vehicle type through the window when driving or parking. For example, users can reconfirm their blind spots when driving by looking at the view visible from the driver seat. For example, the user can confirm, through steps S5 and S6 described below, that the blind spot is that the area around the vehicle body and close to the ground is less visible than that of the vehicle of the second vehicle type, or that the window posts of the vehicle of the first vehicle type are thicker than those of the vehicle of the second vehicle type, thus blocking the view.

Corresponding to the fourth example of the first image, the controller 11 may generate as the second image an image included in a model of the vehicle of the second vehicle type reproduced in the same virtual space as the first image. The virtual space is, for example, a metaverse. For example, the user 21 may be able to re-confirm getting into a vehicle of the second vehicle type recreated in the metaverse, or opening and closing doors, etc.

In S5, the controller 11 transmits the first image generated in S3 to the terminal apparatus 20 of the user 21 via the communication interface 13. The terminal apparatus 20 displays the received first image.

In S6, the controller 11 transmits the second image generated in S4 to the terminal apparatus 20 of the user 21 via the communication interface 13. The terminal apparatus 20 displays the received second image.

In S5 and S6, the controller 11 may simultaneously display the first image generated in S3 and the second image generated in S4 on the terminal apparatus 20. Specifically, the controller 11 may display the first image and the second image side-by-side or overlaid on the terminal apparatus 20. When the first image and the second image are superimposed, it is desirable that the first image and the second image be displayed in a manner that makes them distinguishable, such as one of the images being displayed translucent. In the first example, the controller 11 may display the image of the screen of the navigation system of the vehicle of the first vehicle type and the image of the screen of the navigation system of the vehicle of the second vehicle type side-by-side or superimposed on each other on the screen of the terminal apparatus 20. In the second example, the controller 11 may display the image of the steering wheel of the vehicle of the first vehicle type and the image of the steering wheel of the vehicle of the second vehicle type side-by-side or superimposed on each other on the screen of the terminal apparatus 20. In the third example, the controller 11 may display the images of the view visible from the driver seat through the window of the vehicle of the first vehicle type and the view visible from the driver seat through the window of the vehicle of the second vehicle type side-by-side or superimposed on each other on the screen of the terminal apparatus 20. In the fourth example, the controller 11 may reproduce a model of the vehicle of the first vehicle type and a model of the vehicle of the second vehicle type side by side in the same metaverse. By simultaneously displaying images of the vehicle of the first vehicle type that the user 21 is switching to and the vehicle of the second vehicle type that the user 21 is currently using, the user 21 can learn about changes from the current sense of operation or visibility as a result of the switch.

As another example, in S5 and S6, the controller 11 may selectively display the first image generated in S3 and the second image generated in S4 on the terminal apparatus 20. Specifically, the controller 11 may display the first image generated in S3 and the second image generated in S4 on the terminal apparatus 20 in a way that switches automatically or manually. In the first example, the controller 11 may automatically display an image of the screen of the navigation system of the vehicle of the first vehicle type one second or several seconds after displaying an image of the screen of the navigation system of the vehicle of the second vehicle type on the screen of the terminal apparatus 20. Alternatively, the controller 11 may display an image of the screen of the navigation system of the vehicle of the first vehicle type when the button for switching images is pressed by the user 21 or the screen of the terminal apparatus 20 is swiped sideways by the user 21 after displaying an image of the screen of the navigation system of the vehicle of the second vehicle type on the screen of the terminal apparatus 20. In the second example, the controller 11 may automatically display an image of the steering wheel of the vehicle of the first vehicle type one second or several seconds after displaying an image of the steering wheel of the vehicle of the second vehicle type on the screen of the terminal apparatus 20. Alternatively, the controller 11 may display an image of the steering wheel of the vehicle of the first vehicle type when the button for switching images is pressed by the user 21 or the screen of the terminal apparatus 20 is swiped sideways by the user 21 after displaying an image of the steering wheel of the vehicle of the second vehicle type on the screen of the terminal apparatus 20. In the third example, the controller 11 may automatically display an image of the view visible from the driver seat through the window of the vehicle of the first vehicle type one second or several seconds after displaying an image of the view visible from the driver seat through the window of the vehicle of the second vehicle type on the screen of the terminal apparatus 20. Alternatively, the controller 11 may display an image of the view visible from the driver seat through the window of the vehicle of the second vehicle type, and display an image of the view visible from the driver seat through the window of the vehicle of the first vehicle type when the button for switching images is pressed by the user 21 or the screen of the terminal apparatus 20 is swiped sideways by the user 21. By selectively displaying images of the vehicle of the first vehicle type that the user 21 is switching to and the vehicle of the second vehicle type that the user 21 is currently using, the user 21 can learn about the changes from the current sense of operation or visibility as a result of the switch.

After step S6, the flow illustrated in FIG. 3 ends.

As described above, in SI through S6, the controller 11 communicates with the terminal apparatus 20 of the user 21. The controller 11 acquires the first vehicle type data indicating the type of the vehicle N ordered by the user 21 as the first vehicle type and the second vehicle type data indicating the type of vehicle C used by the user 21 as the second vehicle type. The controller 11 generates a first image representing at least a part of the first field of view range visible in a vehicle of the first vehicle type indicated by the acquired first vehicle type data and a second image representing at least a part of the second field of view range visible in a vehicle of the second vehicle type indicated by the acquired second vehicle type data. The controller 11 transmits both of the generated first image and second image to the terminal apparatus 20 of the user 21.

According to the present embodiment, the user 21 can know the change in the sense of operation or visibility as a result of changing vehicles, which increases convenience.

The present disclosure is not limited to the embodiment described above. For example, two or more blocks described in the block diagram may be integrated, or a block may be divided. Instead of executing two or more steps described in the flowcharts in chronological order in accordance with the description, the steps may be executed in parallel or in a different order according to the processing capability of the apparatus that executes each step, or as required. Other modifications can be made without departing from the spirit of the present disclosure.

1. A control apparatus comprising:
a communication interface configured to communicate with a terminal apparatus of a user; and
a controller configured to:
acquire first vehicle type data indicating a type of a vehicle ordered by the user as a first vehicle type and second vehicle type data indicating a type of a vehicle used by the user as a second vehicle type;
generate a first image representing at least a part of a first field of view range visible in a vehicle of the first vehicle type indicated by the acquired first vehicle type data and a second image representing at least a part of a second field of view range visible in a vehicle of the second vehicle type indicated by the acquired second vehicle type data; and
transmit both of the generated first image and second image to the terminal apparatus of the user via the communication interface.

2. The control apparatus according to claim 1, wherein
the first image includes, as at least the part of the first field of view range, a screen to be displayed on a display mounted in the vehicle of the first vehicle type, and
the second image includes, as at least the part of the second field of view range, a screen to be displayed on a display mounted in the vehicle of the second vehicle type.

3. The control apparatus according to claim 1, wherein
the first image includes, as at least the part of the first field of view range, a physical object to be used for an operation in the vehicle of the first vehicle type, and
the second image includes, as at least the part of the second field of view range, a physical object to be used for an operation in the vehicle of the second vehicle type.

4. The control apparatus according to claim 1, wherein
the first image includes, as at least the part of the first field of view range, a view visible from a driver seat through a window of the vehicle of the first vehicle type, and
the second image includes, as at least the part of the second field of view range, a view visible from a driver seat through a window of the vehicle of the second vehicle type.

5. The control apparatus according to claim 1, wherein
the first image is an image included in a model of the vehicle of the first vehicle type reproduced in a virtual space, and
the second image is an image included in a model of the vehicle of the second vehicle type reproduced in the virtual space.
